(19) United States
(12) Patent Application Publication
(10) Pub. No.: US 2024/0357940 A1
(43) Pub. Date: Oct. 24, 2024

(54) TUNABLE ULTRA-SMALL MONOLITHICALLY-ROLLED-UP COMPONENTS BY PIEZOELECTRIC ACTUATION

(71) Applicant: BOARD OF REGENTS, THE UNIVERSITY OF TEXAS SYSTEM, Austin, TX (US)

(72) Inventors: Xiuling Li, Austin, TX (US); Zhendong Yang, Austin, TX (US); Kristen Nguyen, Austin, TX (US)

(21) Appl. No.: 18/642,050

(22) Filed: Apr. 22, 2024

Related U.S. Application Data
(60) Provisional application No. 63/497,221, filed on Apr. 20, 2023.

(51) Int. Cl. H10N 30/20; H10N 30/05; H10N 30/87

(52) U.S. Cl. CPC H10N 30/204; H10N 30/05; H10N 30/87

(57) ABSTRACT

Disclosed herein is an article including a multilayer sheet configured to be present in a compressive and/or tensile stress, wherein the multilayer sheet is rolled-up to form a curved article, and wherein the multilayer sheet comprises a piezoelectric film configured to tune a radius of curvature of the curved article upon application of an electrical field across the piezoelectric film. Also disclosed are curved, tunable articles configured as L, R, and/or C circuit components. Additionally disclosed are methods of making and using the same.

### CROSS-REFERENCE TO THE CORRELATED APPLICATIONS

This application claims a benefit of the U.S. Provisional Application No. 63/497,221, filed on Apr. 20, 2023, the content of which is incorporated by reference in its entirety.

### BACKGROUND

Although modern-day active electronic devices become smaller and smaller with every chip generation, passive electronic devices, fundamentally consisting of inductors, capacitors, and resistors, remain much larger in size. The miniaturization of these passive electronic components to enable more efficient use of chip area and integration into a wider set of applications has become important to many fields including power electronics and radiofrequency integrated circuits (RFICs). A plethora of microelectromechanical systems-based RF devices with submillimeter dimensions and working frequencies of ˜1-15 GHz have been constructed using structures such as interdigital microelectromechanical systems (MEMS), substrate-integrated waveguides, and airbridge structures. In addition, the increase in wireless technologies, especially with the swift development of the Internet of Things (IoT), has led to the crowding of the RF spectrum, motivating the development of reconfigurable and tunable RF components

Several approaches to tunable RF MEMS passives have been explored. Piezoelectric actuators, which convert electrical energy into a mechanical displacement via the piezoelectric effect, are particularly useful for MEMS applications due to their small size, fast response, lack of electromagnetic interference, and high energy conversion efficiency. Novel piezoelectric thin films, such as the newly emerged aluminum scandium nitride (AlScN), which has high piezoelectric coefficients and electromechanical coupling, are promising for manipulating the lateral displacement of MEMS devices. Piezoelectrically-manipulated tunable RF passives can be integrated into a variety of components, such as tunable filters, tunable impedance matching networks, and multiband amplifiers, enabling wide bandwidth operation in high-frequency regimes.

### SUMMARY

The miniaturization of passive electronic components is essential for radio-frequency integrated circuits (RFICs). In addition, with the surge of wireless technologies, the need for reconfigurable and tunable radiofrequency (RF) components has grown. Enabled by strain-induced self-rolled-up membrane (S-RuM) technology, three-dimensional (3D) tubular interdigital capacitors with greatly reduced footprints can be made with diameter-dependent capacitances. By integrating piezoelectric AlScN, diameter and thus capacitance tuning is demonstrated for the prototyped capacitors, with preliminary data showing a tuning ratio of 1.41 and response of 15.75 pF/V for capacitances of over 150 pF and areal footprints of 0.18 mm². These S-RuM-enabled piezoelectrically-tunable capacitors are easily redesigned to target different capacitances, frequencies, and tuning ratios, with little effect on footprint or process complexity, representing a novel capacitance tuning scheme enabling extreme miniaturization.

Tunable MEMS radio frequency (RF) components made from self-rolled-up MEMS membranes and tunable by piezoelectric actuation are disclosed. In particular, tunable RF MEMS components comprising the piezoelectric material, AlScN, are described.

In one aspect, the tunable MEMS filters are made with self-rolled-up membranes, referred to as S-RuM. The underlying feature of S-RuM is a stress-induced MEMS platform that consists of a sacrificial layer, a compressively stressed, and then a tensile stressed layer deposited subsequently onto the substrate. Upon releasing the sacrificial layer, the compressively stressed layer expands, while the tensile layer opposes that force and pulls back, resulting in the curling of the front of the membrane. As the sacrificial layer continues to get etched, the bilayer membrane rolls up into a tube. S-RuM, in essence, turns a 2D planar-processable membrane into a 3D final product, reducing the footprint of the final product. The precise diameter of the tube can be controlled according to Young's Modulus, Poisson's Ratio, and differential residual stress of the bilayer. The number of turns can be controlled precisely by controlling the rolling length after knowing the diameter. In some aspects, the number of turns can be 0.5, 1, 1.5, 2, 2.5, 3, etc. Finally, S-RuM allows a monolithic array fabrication. A variety of devices can be built on the same substrate all at once, greatly saving cost and development time.

### BRIEF DESCRIPTION OF THE DRAWINGS

FIGS. 1A-1E show schematics of the multilayer sheet including a top view (FIG. 1A), and side views (FIG. 1B-1E) of multilayer sheets having different compositions.

FIG. 2 shows a schematic of the self rolled-up membrane platform.

FIG. 3A shows an example tunable article (FIG. 3A) and related planar structure (FIG. 3B).

FIGS. 4A-4C shows example articles, including a rolled-up article with one turn (FIG. 4A), a rolled-up article with multiple turns (FIG. 4B), and a rolled-up article on a device (FIG. 4C).

FIG. 5 shows an example method of making a curved, tunable article.

FIGS. 6A-6B show an example article including spacers in the planar form (FIG. 6A) and rolled-up form (FIG. 6B).

FIGS. 7A-7C show example configurations of metal-layers forming capacitors and inductors in series and related measurements thereof.

FIG. 8 shows examples of Status A and Status B overlap of opposite polarity interdigital metal patterns and related measurements.

FIG. 9 shows examples of overlap of opposite polarity interdigital metal patterns.

FIG. 10 shows an example of a tunable article.

FIG. 11 shows a schematic of a planar patterning of a metal layer for an RF filter.

FIG. 12A shows an example fabrication processes including i) deposition of Ge, SiNx bilayer, Al (first electrode); ii) pattern/etch of AlScN and deposit Al (second electrode); iii) pattern/etch mesa in AlScN; iv) deposit Al₂O₃ insulating layer and pattern/deposit Au metal layer; v) pattern/etch contact and etch windows.

FIG. 12B shows an example fabrication process: i) Material deposition: Ge sacrificial layer (e-beam evaporation), SiNx stressed bilayer (PECVD), Al bottom electrode (e-beam evaporation), AlScN (sputter); ii) opening of bottom electrode contact window (ICP-RIE); iii) definition of Al top electrode (e-beam evaporation) within partially etched AlScN (ICP-RIE); iv) definition of mesa edges (ICP-RIE); v) deposition of Al₂O₃ cover layer (ALD); vi) definition of Au device layer (e-beam evaporation); vii) opening of etch window in Al₂O₃(BOE) and patterning of photoresist spacers; viii) etching of Ge to induce rolling (XeF₂ vapor etch).

FIGS. 13A-13C show an SEM image of capacitor after rolling (FIG. 13A); microscope images of capacitor before rolling (FIG. 13B) and after rolling (FIG. 13C).

FIGS. 14A-14F show capacitance vs. frequency for a fabricated capacitor with the application of (FIG. 14A) 0 and ±2 V, (FIG. 14B) 0 and ±4 V, and (FIG. 14C) 0 and ±6 V; and zoomed in views (FIGS. 14D-14F) of (FIGS. 14A-14C), respectively.

FIG. 15 shows capacitance and tuning ratio versus voltage for applied voltages of −2 to 2 V at 4.1 MHz.

### DETAILED SPECIFICATION

Some references, which may include various patents, patent applications, and publications, are cited in a reference list and discussed in the disclosure provided herein. The citation and/or discussion of such references is provided merely to clarify the description of the present disclosure and is not an admission that any such reference is “prior art” to any aspects of the present disclosure described herein. In terms of notation, “[n]” corresponds to the n^{th} reference in the list. All references cited and discussed in this specification are incorporated herein by reference in their entirety and to the same extent as if each reference was individually incorporated by reference.

Although example embodiments of the present disclosure are explained in some instances in detail herein, it is to be understood that other embodiments are contemplated. Accordingly, it is not intended that the present disclosure be limited in its scope to the details of construction and arrangement of components set forth in the following description or illustrated in the drawings. The present disclosure is capable of other embodiments and of being practiced or carried out in various ways.

It must also be noted that, as used in the specification and the appended claims, the singular forms “a,” “an,” and “the” include plural referents unless the context clearly dictates otherwise. Ranges may be expressed herein as from “about” or “5 approximately” one particular value and/or to “about” or “approximately” another particular value. When such a range is expressed, other exemplary embodiments include from the one particular value and/or to the other particular value.

By “comprising,” or “containing,” or “including,” it meant that at least the name compound, element, particle, or method step is present in the composition or article or method, but does not exclude the presence of other compounds, materials, particles, method steps, even if the other such compounds, material, particles, method steps have the same function as what is named.

In describing example embodiments, terminology will be resorted to for the sake of clarity. It is intended that each term contemplates its broadest meaning as understood by those skilled in the art and includes all technical equivalents that operate in a similar manner to accomplish a similar purpose. It is also to be understood that the mention of one or more steps of a method does not preclude the presence of additional method steps or intervening method steps between those steps expressly identified. Steps of a method may be performed in a different order than those described herein without departing from the scope of the present disclosure. Similarly, it is also to be understood that the mention of one or more components in a device or system does not preclude the presence of additional components or intervening components between those components expressly identified.

The expressions “ambient temperature” and “room temperature” as used herein are understood in the art and refer generally to a temperature from about 20° C. to about 35° C.

As used herein, the term “composition” is intended to encompass a product comprising the specified ingredients in the specified amounts, as well as any product which results, directly or indirectly, from a combination of the specified ingredients in the specified amounts.

References in the specification and concluding claims to parts by weight of a particular element or component in a composition denotes the weight relationship between the element or component and any other elements or components in the composition or article for which a part by weight is expressed. Thus, in a mixture containing 2 parts by weight of component X and 5 parts by weight, components Y, X, and Y are present at a weight ratio of 2:5 and are present in such a ratio regardless of whether additional components are contained in the mixture.

A weight percent (wt. %) of a component, unless specifically stated to the contrary, is based on the total weight of the formulation or composition in which the component is included.

It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”).

As used herein, the term “curved” is intended to encompass any structure that may be described by its curvature. The structures encompassed by “curved” include, but are not limited to, tubular, spiral, helical, serpentine, and rolled-up.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in their respective testing measurements. Furthermore, when numerical ranges of varying scope are set forth herein, it is contemplated that any combination of these values inclusive of the recited values may be used. Further, ranges can be expressed herein as from “about” one particular value and/or to “about” another particular value. When such a range is expressed, another aspect includes from the one particular value and/or to the other particular value.

Similarly, when values are expressed as approximations, by use of the antecedent “about,” it will be understood that the particular value forms another aspect. It will be further understood that the endpoints of each of the ranges are significant both in relation to the other endpoint and independently of the other endpoint. Unless stated otherwise, the term “about” means within 5% (e.g., within 2% or 1%) of the particular value modified by the term “about.”

Similarly, numerical ranges recited herein by endpoints include subranges subsumed within that range (e.g., 1 to 5 includes 1-1.5, 1.5-2, 2-2.75, 2.75-3, 3-3.90, 3.90-4, 4-4.24, 4.24-5, 2-5, 3-5, 1-4, and 2-4). It is also to be understood that all numbers and fractions thereof are presumed to be modified by the term “about.”

It will be understood that although the terms “first,” “second,” etc., may be used herein to describe various elements, components, regions, layers, and/or sections. These elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” “bottom,” “top,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein are interpreted accordingly.

As used herein, the term “substantially” means that the subsequently described event or circumstance completely occurs or that the subsequently described event or circumstance generally, typically, or approximately occurs.

Still further, the term “substantially” can, in some aspects, refer to at least about 80%, at least about 85%, at least about 90%, at least about 91%, at least about 92%, at least about 93%, at least about 94%, at least about 95%, at least about 96%, at least about 97%, at least about 98%, at least about 99%, or about 100% of the stated property, component, composition, or other condition for which substantially is used to characterize or otherwise quantify an amount.

In other aspects, as used herein, the term “substantially free,” when used in the context of a composition or component of a composition that is substantially absent, is intended to refer to an amount that is then about 1% by weight, e.g., less than about 0.5% by weight, less than about 0.1% by weight, less than about 0.05% by weight, or less than about 0.01% by weight of the stated material, based on the total weight of the composition.

As used herein, the terms “substantially identical reference composition,” “substantially identical reference article,” or “substantially identical reference electrochemical cell” refer to a reference composition, article, or electrochemical cell comprising substantially identical components in the absence of an inventive component. In another exemplary aspect, the term “substantially,” in, for example, the context “substantially identical reference composition,” or “substantially identical reference article,” or “substantially identical reference electrochemical cell” refers to a reference composition, article, or an electrochemical cell comprising substantially identical components and wherein an inventive component is substituted with a common in the art component.

The devices, systems, and methods of the appended claims are not limited in scope by the specific devices, systems, and methods described herein, which are intended as illustrations of a few aspects of the claims. Any devices, systems, and methods that are functionally equivalent are intended to fall within the scope of the claims. Various modifications of the devices, systems, and methods, in addition to those shown and described herein, are intended to fall within the scope of the appended claims. Further, while only certain representative devices, systems, and method steps disclosed herein are specifically described, other combinations of the devices, systems, and method steps also are intended to fall within the scope of the appended claims, even if not specifically recited. Thus, a combination of steps, elements, components, or constituents may be explicitly mentioned herein or less; however, other combinations of steps, elements, components, and constituents are included, even though not explicitly stated.

Although several embodiments have been disclosed in the foregoing specification, it is understood by those skilled in the art that many modifications and other embodiments will come to mind to which may be pertinent, having the benefit of the teaching presented in the foregoing description and associated drawings. It is thus understood that the subsequent claims are not limited to the specific embodiments disclosed hereinabove and that many modifications and other embodiments are intended to be included within the scope of the appended claims. Moreover, although specific terms are employed herein, as well as in the claims which follow, they are used only in a generic and descriptive sense and not for the purposes of limiting the claims which follow.

Unless defined otherwise, all technical and scientific terms used herein have the same meanings as commonly understood by one of skill in the art to which the disclosure belongs. Publications cited herein and the materials for which they are cited are specifically incorporated by reference.

While aspects can be described and claimed in a particular statutory class, such as the system statutory class, this is for convenience only and one of ordinary skill in the art will understand that each aspect can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is in no way intended that an order be inferred in any respect. This holds for any possible non-express basis for interpretation, including matters of logic with respect to the arrangement of steps or operational flow, plain meaning derived from grammatical organization or punctuation, or the number or type of aspects described in the specification.

In view of the described processes and compositions, hereinbelow are described certain more particularly described aspects and embodiments. These particularly recited aspects should not, however, be interpreted to have any limiting effect on any different claims containing different or more general teachings described herein or that the “particular” aspects are somehow limited in some way other than the inherent meanings of the language and formulas literally used therein.

The appended claims can be understood more readily by reference to the following detailed description of various aspects and the examples included therein and to the Figures and their previous and following description.

The self-rolled-up membrane (S-RuM) platform is a MEMS approach that allows monolithic, 2D processing of planar designs to form complex 3D cylindrical multiturn architectures. The platform can be made CMOS-compatible. The transformation from planar to 3D results in extreme miniaturization of areal footprints to less than 0.1 mm², while allowing for high inductance and capacitance densities due to the compact and overlapping, cylindrical nature of the devices.

The integration of piezoelectric materials to the S-RuM platform allows tuning of the device diameter without additional fabrication complexity or footprint, in comparison to current piezoelectrically-tunable filters that require complex 3D fabrication processes or large 2D footprints. Tuning in the 1 MHz to 100 GHz regime is possible by optimizing the structure to target the MHz regime, as will be described below.

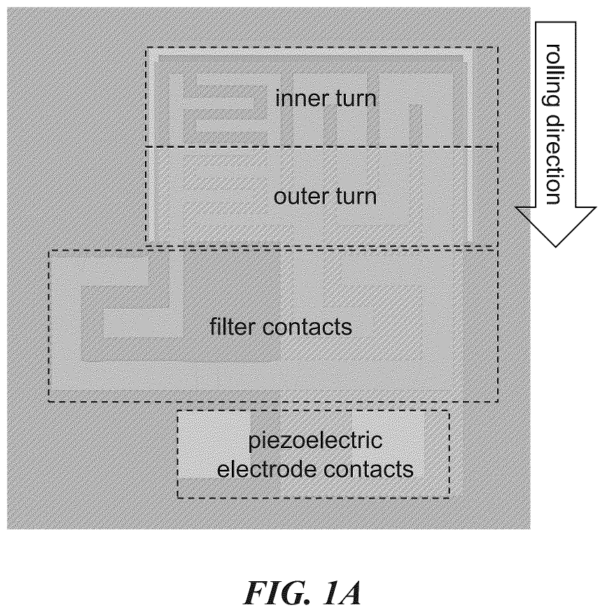

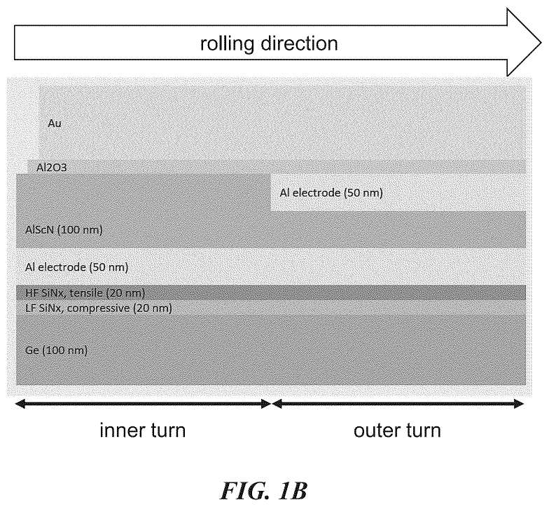

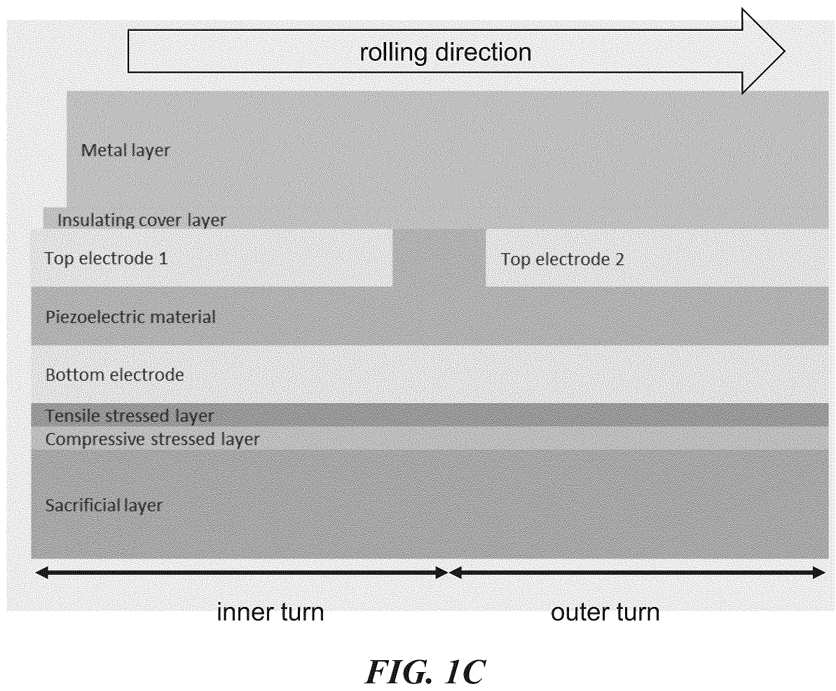

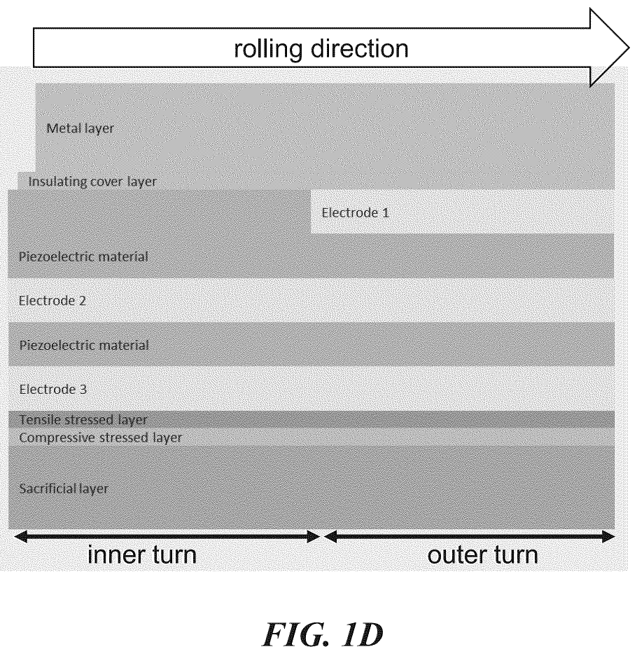

In one aspect, the tunable MEMS filters are made with self-rolled-up membranes, referred to as S-RuM. The underlying feature of S-RuM is a stress-induced MEMS platform that consists of a sacrificial layer, a compressively stressed, and then a tensile stressed layer deposited subsequently onto the substrate (see FIG. 1A), resulting in a strained bilayer. Upon releasing the sacrificial layer, the compressively stressed layer expands, while the tensile layer opposes that force and pulls back, resulting in the curling of the front of the membrane. As the sacrificial layer continues to get etched, the bilayer membrane eventually rolls up into a tube, thus turning a 2D planar-processable membrane into a 3D final product, reducing the footprint of the final product. The precise diameter of the tube can be controlled according to Young's Modulus, Poisson's Ratio, and differential residual stress of the bilayer. The number of turns can be controlled precisely by controlling the rolling length after knowing the diameter. In some aspects, the number of turns can be 0.5, 1, 1.5, 2, 2.5, 3, etc. Finally, S-RuM allows a monolithic array fabrication. A variety of devices can be built on the same substrate all at once, greatly saving cost and development time.

An exemplary embodiment of the disclosure is shown in FIG. 1A, a multilayer sheet configured to be present in a compressive and/or tensile stress state. The multilayer sheet includes a piezoelectric film, a first electrode and a second electrode, wherein the piezoelectric film is disposed between the first and the second electrodes (see FIG. 1B). In some aspects, the multilayer sheet is rolled-up to form a curved article, wherein the piezoelectric film tunes a radius of curvature of the article upon application of an electric voltage across the piezoelectric film. It should be understood that the disclosure contemplates that the multilayer sheet is present in a planar form before forming the curved article.

In some aspects, the planar multilayer sheet further includes a strained layer, wherein the strained layer includes two layers, and wherein, a first layer is in tension, and a second layer is in compression. In some aspects, the first layer is on a top side and the second layer is on a bottom side. In other aspects, the first layer is on the bottom side and the second layer is on the top side. In yet other aspects, the strained layer includes a gradient of compression stress and/or tension stress. In some examples, the top side is primarily in tension and the bottom side is primarily in compression. In some aspects, the composition is a gradient from the topmost composition in tension and the bottom most composition in compression. In other aspects, the gradient of compression to tension is a result of varied deposition conditions. In yet other aspects, the strained layer is primarily in compression on the bottom side and the compressive stress gradually decreases toward the top side. In yet other aspects, the strained layer is in tension on the top side and the tensive stress gradually decreases toward the bottom side. When the multilayer sheet is rolled-up to form of a curved article, the strained layer is relieved, thus forming a strain-relieved layer of the curved article.

In some aspects, the multilayer sheet further includes a third electrode, wherein the first electrode is laterally aligned with the second electrode, and wherein the piezoelectric film is disposed between the third electrode on a bottom side and the first and second electrodes on a top side. The top side of the piezoelectric film is etched such that a portion of the piezoelectric film is between the first and second electrode, as shown in FIG. 1C.

In some aspects, the multilayer sheet further includes a second piezoelectric film. In some aspects, the multilayer sheet further includes a third electrode, wherein the second piezoelectric film is disposed between the second electrode and the third electrode, as shown in FIG. 1D.

In some aspects, the multilayer sheet further includes a fourth electrode, wherein the second piezoelectric film is disposed between the third and fourth electrode. In some aspects, the multilayer sheet further includes a fifth electrode, wherein the fourth electrode and the fifth electrode are laterally aligned and separated by a portion of the second piezoelectric film. The second piezoelectric film being disposed between the third electrode and the fourth and fifth electrodes, as shown in FIG. 1E. It should be understood that the arrangement of piezoelectric films and electrodes are for example only. The disclosure contemplates any suitably functional arrangement.

In some aspects, the piezoelectric film and/or second piezoelectric film has a thickness of about 1 nm to about 10 μm, about 10 nm to about 10 μm, about 100 nm to about 10 μm, about 1 μm to about 10 μm, about 1 nm to about 1 μm, about 1 nm to about 100 nm, or about 1 nm to about 10 nm. For example, the piezoelectric film is about 1 nm, about 10 nm, about 100 nm, about 1 μm, or about 10 μm. In some aspects, the piezoelectric film is patterned and/or etched.

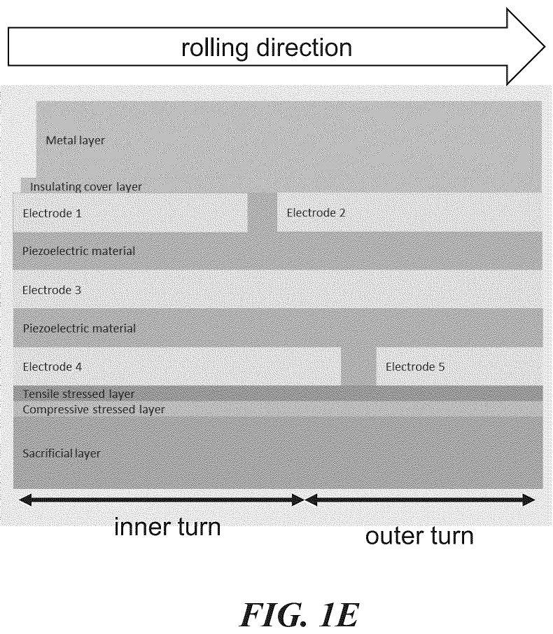

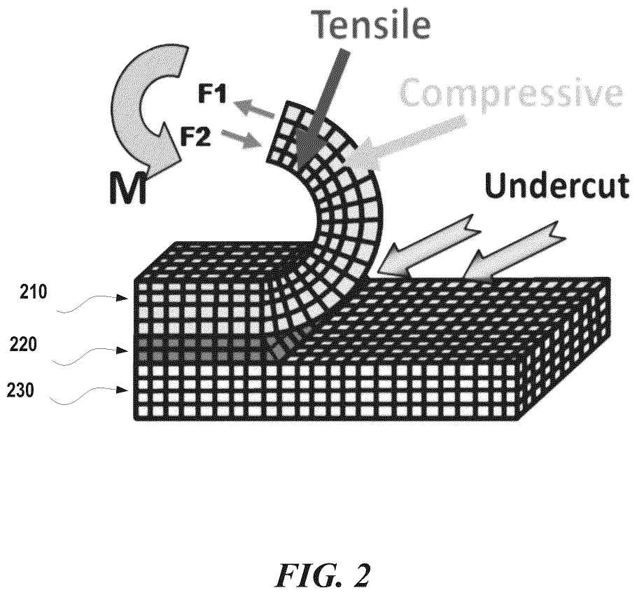

Referring now to FIG. 2, the planar form of the multilayer sheet further includes a substrate 230, on top of which is a sacrificial layer 220 followed by the strain-relieved layer 210, further on top of which the first and second electrodes and piezoelectric film are disposed.

The multilayer sheet forms a self-rolled-up membrane (S-RuM) of MEMs, which utilizes residual stress in the strain-relieved layer to roll up the planar multilayer sheet into 3D cylindrical multiturn architectures with <0.1 mm² areal footprint.

In some aspects, the areal footprint is about 10 mm² or less, about 8 mm² or less, about 6 mm² or less, about 4 mm² or less, about 2 mm² or less, about 1 mm² or less, about 0.8 mm² or less, about 0.6 mm² or less, about 0.4 mm² or less, about 0.2 mm² or less, or about 0.1 mm² or less.

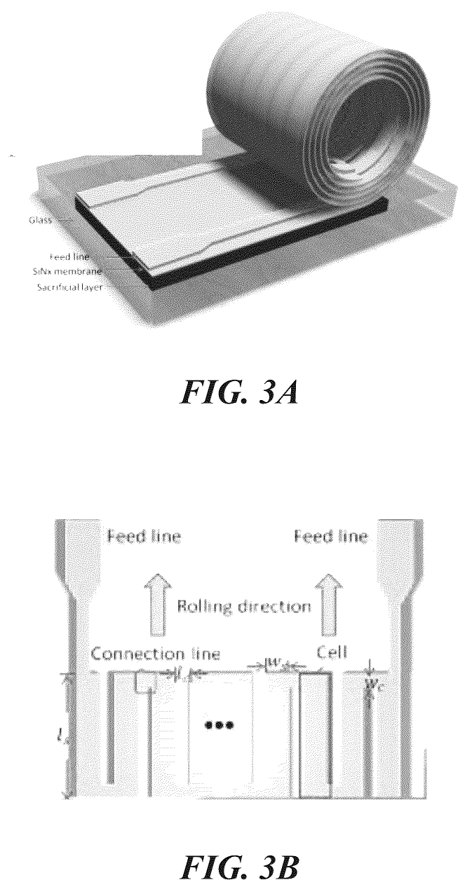

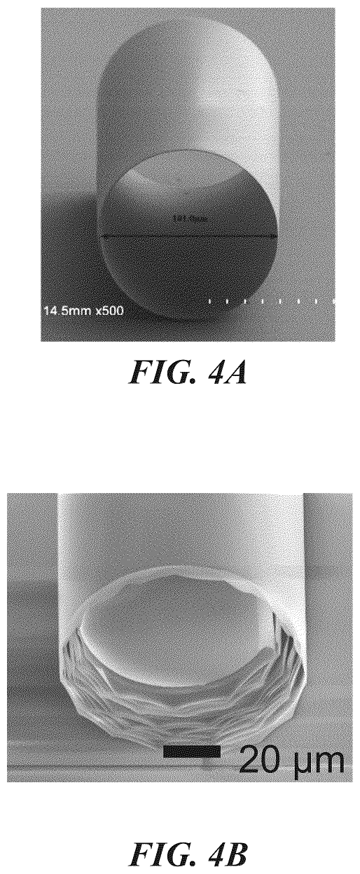

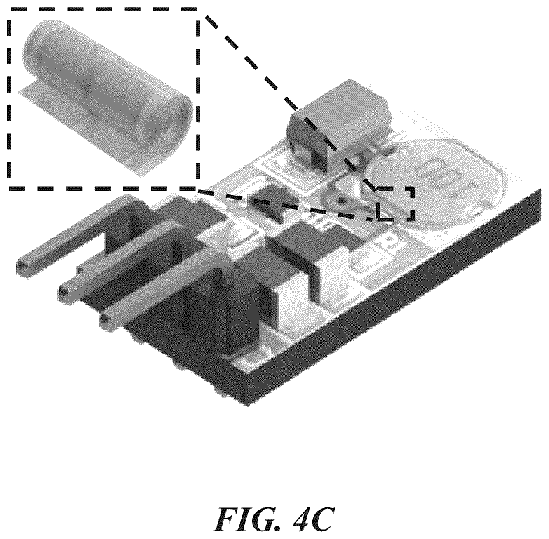

In some aspects, the sacrificial layer 220 is selectively etched from the planar multilayer sheet, which releases the strain-relieved layer 210 and subsequently curls up due to the expansion of the compressively strained layer and the contraction of the tensile stressed layer, as shown in FIG. 2. Resulting in the planar multilayer sheet transforming into a rolled-up tube (see FIG. 3A). The process has directional control, dependent on the etch window orientation and can be rolled into many turns. In some aspects, the number of turns can be 0.5, 1, 1.5, 2, 2.5, 3, etc. For example, as shown in FIGS. 4A and 4B.

In some aspects, the curved article is a tubular, spiral, or helical form. In some aspects, the article has a 3D cylindrical multiturn architecture. In other aspects, the article forms a buckle-up or buckle-down shape in response to the release of the sacrificial layer.

In some aspects, the multilayer sheet further includes an insulating cover layer disposed atop the uppermost electrode layer.

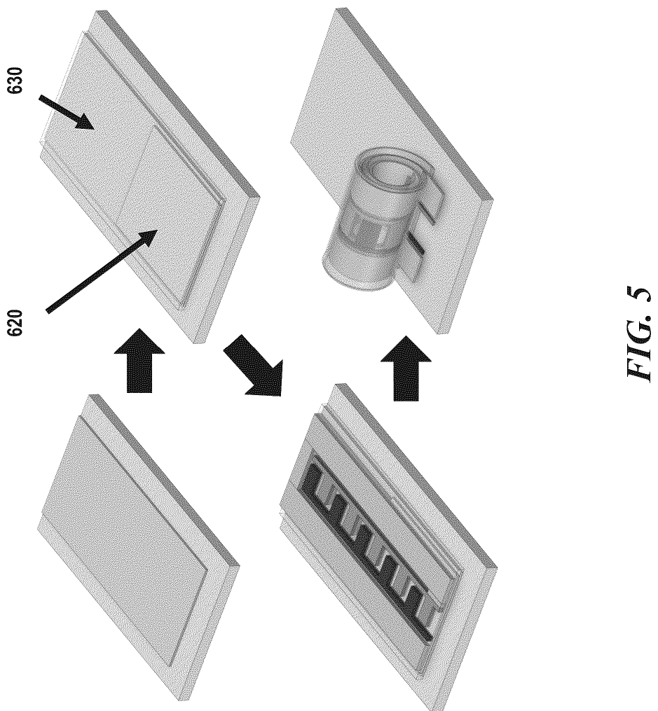

In some aspects, the multilayer sheet further includes a metal layer, wherein the metal layer is patterned to form an inductor and/or conductor and/or resistor in the rolled-up form. For example, the metal layer is patterned to form an interrelated pattern. In the rolled-up form, the alignment of the interrelated pattern in a first turn and a second turn is changed, thus creating a tunable capacitor, inductor, resistor, or combinations thereof (see FIG. 5).

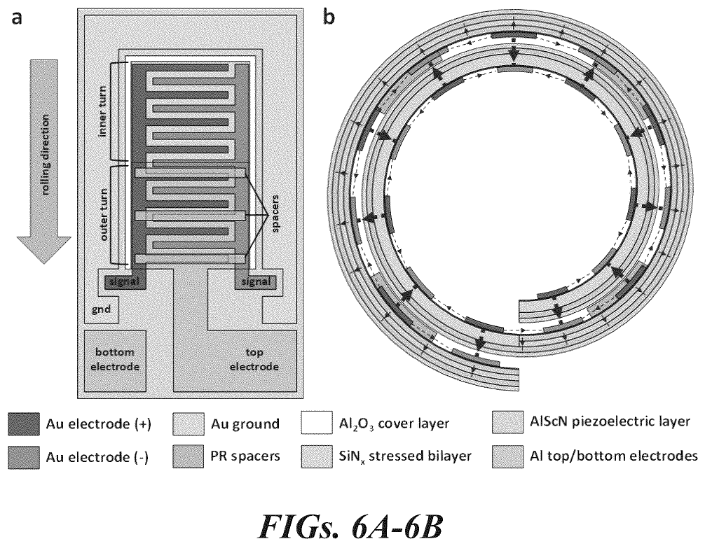

In some aspects, the multilayer sheet further includes spacers disposed atop the metal layer, which provides for a minimum distance between rolled-up layers. The spacer is one of a photoresist material or Au, Al, Cu, Ni, Ti, Cr, Pt, etc. The spacers prevent short circuiting in the curved article. An example multilayer sheet including spacer is shown in FIG. 6. A photoresist material includes one or more light-sensitive polymers and optionally a binding material. In preferred examples, photoresist materials produced by Merck, such as AZ 5209 E, AZ 5214 E, TI 35 E, T135ESX, AS 125nXT, AS 15nXT, AZ nLof 2020, AZ nLof 2035, AZ nLof 2070, AZ nLof 5510, AZ 1505, AZ 1512 HS, AZ 1514 H, AZ 1518, AZ MIR 701, AZ ECI 3007, AZ ECI 3012, AZ ECI 3027, AS TFP 650, among others can be used in the formation of the spacers.

In some aspects, the spacers are rectangular prisms, with widths from about 10 μm to about 1 cm such that the spacers span the width of the device. In some aspects, the spacer width is about 100 μm to about 1 cm, about 1 mm to about 1 cm, about 10 mm to about 1 cm, about 100 mm to about 1 cm, about 10 μm to about 100 mm, about 1 μm to about 10 mm, about 1 μm to about 1 mm, about 1 μm to about 100 μm, or about 1 μm to about 10 μm.

In some aspects, the spacer lengths range from about 1 μm to about 100 μm, and spacer thicknesses range from about 10 nm to 5 μm. In some aspects, the spacers are spaced about 1 to 1000 μm apart uniformly across the device.

In some aspects, the spacer lengths range from 1 μm to about 50 μm, about 1 μm to about 25 μm, about 1 μm to about 10 μm, about 10 μm to about 100 μm, about 25 μm to about 100 μm, about 50 μm to about 100 μm, about 10 μm to about 25 μm, about 10 μm to about 50 μm, or about 25 μm to about 50 μm.

In some aspects, the space thicknesses range from about 50 nm to about 5 μm, about 100 nm to about 5 μm, about 1 μm to about 5 μm, about 10 nm to about 1 μm, about 10 nm to about 100 nm, about 10 nm to about 50 nm, about 50 nm to about 100 nm, or about 100 nm to about 1 μm.

In some aspects, the spacers are spaced about 10 μm to about 1000 μm, about 100 μm to about 1000 μm, about 500 μm to about 1000 μm, about 10 μm to about 500 μm, about 10 μm to about 100 μm, or about 100 μm to about 500 μm.

As shown in FIGS. 6A-6B, the spacers are disposed on the outer turn of the multilayer sheet, however, the disclosure contemplates that the spacers can be located on all turns of the device, including for curved articles with more than two turns.

In some aspects, the piezoelectric film includes one or more of ZnO, AlN, BNT, PVDF, LiNbO3, or AlXN, where X is chosen from Sc, B, Er, Cr, Ti, V, Y, Yb, Ta, Mg, Zr, Nb, In, Li, or combinations thereof. For example, the piezoelectric film includes (AlₓSc_{y})₁N, (AlₓCr_{y})₁N, (AlₓBy)₁N, (AlₓTi_{y})₁N, (AlₓTa_{y})₁N, (AlₓY_{y})₁N, (AlₓYb_{y})₁N, (AlₓGa_{y})₁N, (AlₓEr_{y})₁N, (AlₓIn_{y})₁N, (AlₓV_{z}Ta_{y})₁N, (AlₓMg_{z}Hf_{y})₁N, (AlₓMg_{z}Si_{y})₁N, (AlₓMg_{z}Ti_{y})₁N, (AlₓMg_{z}Zr_{y})₁N, (AlₓTi_{z}Ca_{y})₁N, (AlₓTi_{z}Zn_{y})₁N, (AlₓZr_{z}Ca_{y})₁N, (AlₓZr_{z}Zn_{y})₁N, (AlₓHf_{z}Ca_{y})₁N, (AlₓHf_{z}Zn_{y})₁N, (AlₓMg_{z}Nb_{y})₁N, (AlₓLi_{z}Nb_{y})₁N, (AlₓLi_{z}Ta_{y})₁N, or (AlₓLi_{z}Zr_{y})₁N [10]. The disclosure contemplates that the piezoelectric film includes other suitable piezoelectric materials.

In some aspects, suitable piezoelectric materials may be those having a range of piezoelectric coefficient d33 of about 5 to 150 pm/V and d31 of about −5 to −50 pm/V and is pliable (e.g., non-brittle). In some aspects, the piezoelectric film is etched to provide conduits for one or more electrodes and/or to form a mesa, which designates the portion of the multilayer sheet in the second turn (see FIG. 5).

In some aspects, the first, second, third, fourth, and/or fifth electrode include aluminum material.

In some aspects, the composition of the strain-relieved layer includes SiNₓ and/or AlN in varying proportions.

In some aspects, the sacrificial layer includes Ge. In some aspects, the substrate is a glass substrate or sapphire substrate.

Disclosed herein is a device including the curved article as described in any variation above. In some aspects, the curved article is on a substrate (see FIG. 4C). In other aspects, the curved article is fixed on both ends (i.e. suspended) as part of the device, such that the diameter of the curved article freely expands and contracts.

In some aspects, a tunable article is disclosed, wherein the tunable article is an L, R, and/or C circuit component or any combination thereof. The tunable article includes a multilayer sheet in a rolled configuration including: a strain-relieved layer; a first electrode layer; a piezoelectric layer; a second electrode layer; and a metal-containing layer, wherein the metal-containing layer is patterned. In some aspects, the first and second electrodes are exposed on an outside of the tunable article for electrical contact with a voltage supply, wherein a diameter of the multilayer sheet is tuned by applying an electric voltage across the tunable article.

In some aspects, the tunable article is tunable in an about 1 MHz to about 100 GHz frequency range, about 10 MHz to about 100 GHz, about 100 MHz to about 100 GHz, about 1 GHz to about 100 GHz, about 10 GHz to about 100 GHz, about 1 MHz to about 10 GHz, about 1 MHz to about 1 GHz, about 1 MHz to about 100 MHz, or about 1 MHz to about 10 MHz. It is contemplated that the tunable article is tuned to operate in the appropriate frequency range.

In some aspects, the tunable article, when the multilayer sheet is in a rolled configuration, includes one or more turns about a longitudinal axis, and wherein the rolled configuration of the multilayer sheet has an on-wafer footprint of about 10 mm² or less. In some aspects, the on-wafer footprint is about 10 mm² or less, about 8 mm² or less, about 6 mm² or less, about 4 mm² or less, about 2 mm² or less, about 1 mm² or less, about 0.8 mm² or less, about 0.6 mm² or less, about 0.4 mm² or less, about 0.2 mm² or less, about 0.1 mm² or less.

In some aspects, the tunable article, in a planar form, further includes a strained layer, wherein the strained layer includes two layers, and wherein, a first layer is in tension, and a second layer is in compression. In some aspects, the first layer is on a top side and the second layer is on a bottom side of the strained layer. In other aspects, the first layer is on the bottom side and the second layer is on the top side of the strained layer. In yet other aspects, the strained layer includes a gradient of compression stress and/or tension stress. In some examples, the top side is primarily in tension and the bottom side is primarily in compression. In some aspects, the composition is a gradient from the topmost composition in tension and the bottom most composition in compression. In other aspects, the gradient of compression to tension is a result of varied deposition conditions. In yet other aspects, the strained layer is primarily in compression on the bottom side and the compressive stress gradually decreases toward the top side. In yet other aspects, the strained layer is in tension on the top side and the tensive stress gradually decreases toward the bottom side. When the multilayer sheet is rolled-up to form a curved article, the strained layer is relieved, thus forming a strain-relieved layer of the curved article.

In some aspects, the tunable article includes the metal-containing layer, which includes an interrelated pattern, that when in the rolled configuration, forms a rolled-up inductor, capacitor, resistor, or combinations thereof on the strain-relieved layer.

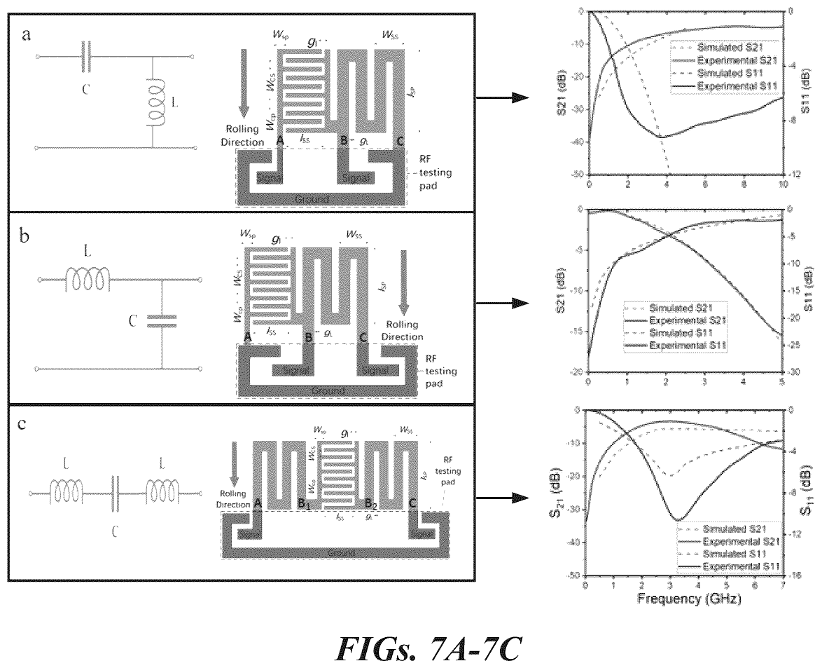

It is contemplated that the tunable article may include any combination of inductors, capacitors, and/or resistors. For example, the tunable article includes a capacitor and inductor in series, an inductor and capacitor in series, an inductor, a capacitor, and a second inductor in series, as shown in FIGS. 7A-7C.

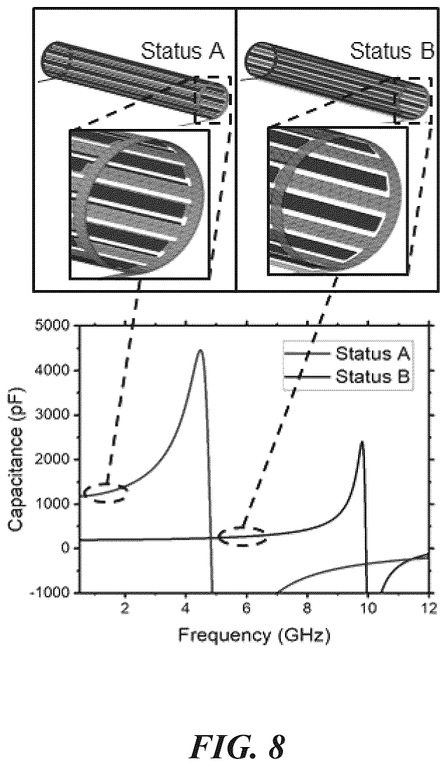

In some aspects, the tunable article is tuned by expanding or compressing the diameter of the rolled multilayer sheet, causing the rolled up interrelated pattern to partially or fully overlap (e.g., the conductive layers are in the A or B configurations, as shown in FIG. 8).

In some aspects, the tunable article further includes spacers disposed atop the metal layer, which provides for a minimum distance between rolled-up layers. The spacer is one of a photoresist material or Au, Al, Cu, Ni, Ti, Cr, Pt, etc. The spacers prevent short circuiting in the curved article. An example multilayer sheet including spacer is shown in FIG. 6. A photoresist material includes one or more light-sensitive polymers and optionally a binding material. In preferred examples, photoresist materials produced by Merck, such as AZ 5209 E, AZ 5214 E, TI 35 E, T135ESX, AS 125nXT, AS 15nXT, AZ nLof 2020, AZ nLof 2035, AZ nLof 2070, AZ nLof 5510, AZ 1505, AZ 1512 HS, AZ 1514 H, AZ 1518, AZ MIR 701, AZ ECI 3007, AZ ECI 3012, AZ ECI 3027, AS TFP 650, among others can be used in the formation of the spacers.

In some aspects, the tunable article is an L-R-C filter network, L-C filter network, L-circuit component, R-circuit component, C-circuit component, L-R-C-filter network, antenna, transformer, switch, valve, or any combination thereof.

Here, the concept of Status A and Status B as shown in FIG. 8 is discussed. Depending on the design parameters and the bilayer stress, the tunable device is designed to roll up into status A or B extremes or somewhere in between. The difference between A and B here is that for Status A, the overlapping capacitance is maximized as the fingers from the left “hand” side overlap exactly with fingers from the right “hand” side. This produces a maximum while if the overlapping occurs between fingers from the same hand, the capacitance coupling between turns introduced is 0. The piezoelectric layer provides for expansion/contraction of the out turn, thereby the alignment between fingers can be tuned to achieve tunable devices.

As defined, Status A is when the maximum overlap of fingers with opposite polarity between turns occurs, resulting in maximum capacitance. Status B is when the minimum overlap occurs, resulting in minimal capacitance. The capacitance can be determined as follows:

$$\begin{matrix}\begin{matrix}\begin{matrix}Between \\ fingers \text{:}\end{matrix} & {C}_{p} = ( \frac{{ε}_{r} + 1}{w} ) {l}_{f} [ ( N - 3 ) {A}_{1} + {A}_{2} ]\end{matrix} \\ \begin{matrix}\begin{matrix}Overlap \\ ( Status A ) :\end{matrix} & {C}_{c} = ( \frac{{ε}_{d} ( N - 1 )}{{t}_{d}} ) {nw}_{f} {l}_{f}\end{matrix} \\ \begin{matrix}\begin{matrix}Overlap \\ ( Status B ) :\end{matrix} & {C}_{c} = 0\end{matrix}\end{matrix}$$

In some aspects, the tunable article can be viewed as two concentric circles with transverse extension of the outer turn. The extension of the outer turn can be found using the following equation for transverse piezoelectric displacement:

$$Δ l = {d}_{31} \frac{l}{h} V$$

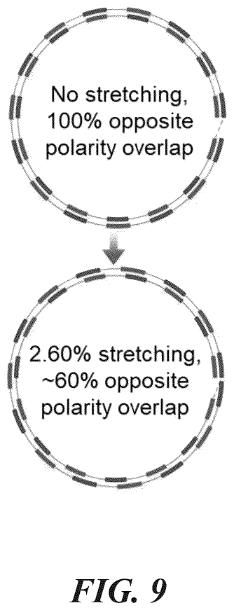

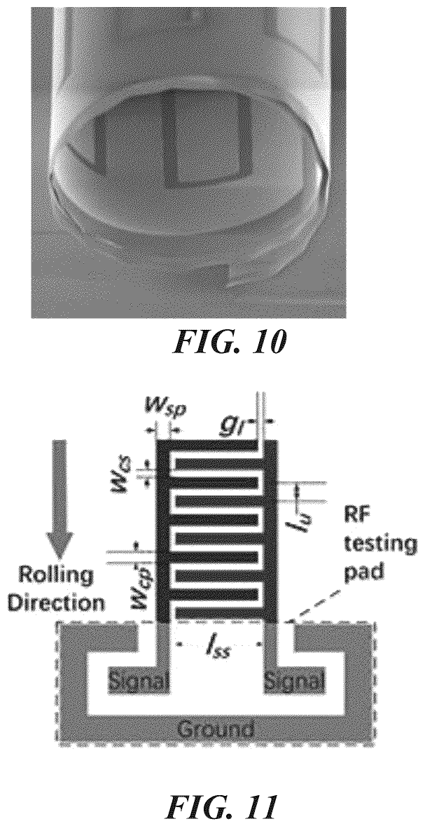

For an exemplary tunable device, the piezoelectric material has a transverse piezoelectric coefficient of −13 pm/V for a 0.9 um thick film. The piezoelectric, AlScN, layer is 50 nm thick, which is optimized for maintaining a high piezoelectric coefficient and allowing ease of rolling. According to the equation above, the predicted extension of the outer turn is approximately 2.6 um, which is a 2.6% stretching of the outer turn. As shown in FIG. 9, there is an approximately 60% overlap between fingers of opposite polarity on different turns, in comparison to the 100% overlap shown.

The above equation of Status A overlap is used to compute capacitance of the exemplary tunable article based on the values of Table 1, which is 127 fF. When the outer turn is stretched, the capacitance can be tuned to 60% of this value, or 76 fF.

The exemplary tunable article, acting as a capacitor, can be combined with a 1 nH typical value for a 2-turn S-RuM inductor to make an LC filter. This filter can achieve center frequency tuning between 14 to 18 GHz. However, by further optimizing the inductor and capacitor, higher frequencies can be achieved (i.e. greater than 50 GHz).

TABLE 1
Constants for an Example Article.

| | Symbol | Value | |
|---|---|---|---|
| Transverse piezoelectric coefficient | d₃₁ | −13 | pm/V |
| Diameter of outer turn | dₒᵤₜₑᵣ | 32 | μm |
| Length (circumference) of outer turn | l | πdₒᵤₜₑᵣ | |
| Thickness of AlScN | h | 50 | nm |
| Applied voltage | V | 100 | V |
| Length of fingers | l_{f} | 200 | μm |
| Width of fingers | w_{f} | 4 | μm |
| Thickness of SiNₓ | t_{SiNx} | 40 | nm |
| Dielectric constant of SiNₓ | ε_{r, SiNx} | 7 | |
| Thickness of Al₂O₃ | t_{Al2O3} | 5 | nm |
| Dielectric constant of Al₂O₃ | ε_{r, Al2O3} | 9 | |
| Thickness of air gap | tₐᵢᵣ | 830 | nm |

| | | |
|---|---|---|
| Number of fingers per turn | n_{f} | 15 |

The example capacitor device made from fabricated material with integrated piezoelectric materials between layers can be tuned by an alignment between fingers by an external force, which results in tunable capacitors. The external force can be an externally applied voltage.

Tuning is most evident in the interdigital capacitor, as switching from Status A to Status B maximizes and minimizes the overlap capacitance, respectively. In the example of a rolled-up capacitor, the outer turn stretches to shift the finger overlap away from status A's maximum overlap. In other example designs, the finger overlap could be minimized, that is, to shift away from status B to target lower capacitances. The extension of the outer turn can be computed based on the piezoelectric coefficient of the active material and the applied voltage.

In one example, a 50 nm thick AlScN, Al_{0.7}Sc_{0.3}N, layer was used, which optimized the piezoelectric coefficient and ease of rolling. When the overlap capacitance is 100%, a maximum capacitance can be achieved. When there is an approximately 60% overlap between fingers of opposite polarity on different turns, the capacitance can be tuned to 60% of the maximum value. Combining this with a 1 nH typical value for a two-turn S-RuM inductor to make an L-C filter, the example filter can achieve center frequency tuning several GHz. However, by further optimizing the inductor and capacitor, it is contemplated that higher frequencies, aiming for over 50 GHz, are achievable.

Disclosed herein is a device including the tunable article as described in any variation above. In some aspects, the curved article is on a substrate (see FIG. 4C). In other aspects, the curved article is fixed on both ends (i.e. suspended) as part of the device, such that the diameter of the curved article freely expands and contracts.

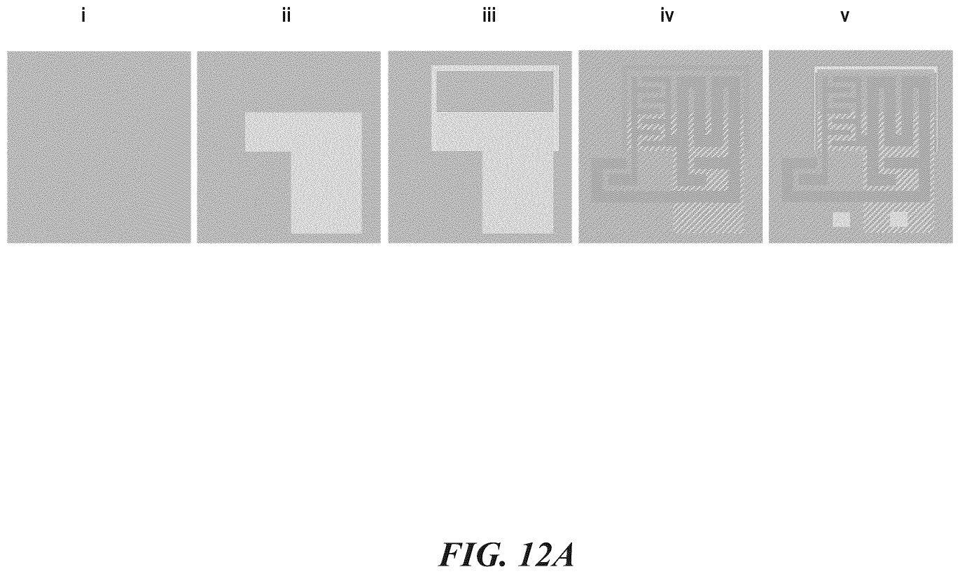

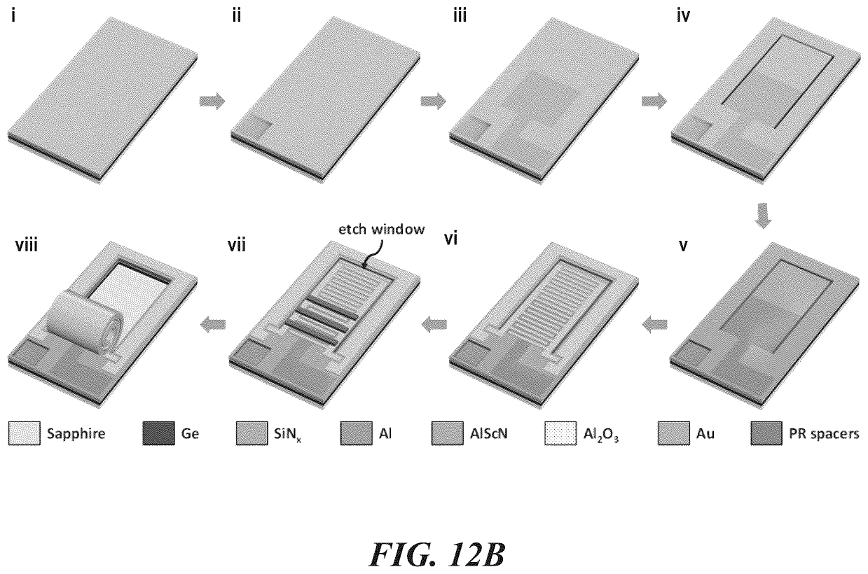

In some aspects, the disclosure is related to a method of making a curved article. The method includes forming a sacrificial layer on a substrate; forming a strain layer on the sacrificial layer, the strain layer including an upper portion under tensile stress and a lower portion under compressive stress, the strain layer being held on the substrate by the sacrificial layer; forming a piezoelectric layer on the strain layer, the piezoelectric layer including a first electrode, a thin film of piezoelectric material, and a second electrode (see FIG. 12). The method further includes removing of the sacrificial layer from the substrate, thereby releasing an end of the strain layer, forming a strain-relieved layer, wherein the strain-relieved layer moves away from the substrate, forming a curved article (see FIG. 2).

In some aspects, the method further includes disposing a third electrode, wherein the third electrode is adjacent to the piezoelectric film and laterally aligned with the second electrode, and wherein the piezoelectric film is disposed between the first electrode on a bottom side and the second and third electrodes on a top side. The top side of the piezoelectric film is etched such that a portion of the piezoelectric film is between the second and third electrode.

In some aspects, the method further includes disposing a second piezoelectric film and a third electrode, wherein the second piezoelectric film is disposed between the first electrode and the third electrode.

In some aspects, the method further includes disposing a fourth electrode, wherein the second piezoelectric film is disposed between the third and fourth electrode. In some aspects, the method includes disposing a fifth electrode, wherein the fourth electrode and the fifth electrode are laterally aligned in the same layer and separated by a portion of the second piezoelectric film, the second piezoelectric film being disposed between the third electrode and the fourth and fifth electrodes. It should be understood that the arrangement of piezoelectric films and electrodes are for example only. The disclosure contemplates any suitably functional arrangement.

In some aspects, the piezoelectric film is formed by epitaxial growth, atomic layer deposition, or sputtering of the piezoelectric material. In some aspects, the piezoelectric film has a thickness of about 1 nm to about 10 μm, about 10 nm to about 10 μm, about 100 nm to about 10 μm, about 1 μm to about 10 μm, about 1 nm to about 1 μm, about 1 nm to about 100 nm, or about 1 nm to about 10 nm. For example, the piezoelectric film is about 1 nm, about 10 nm, about 100 nm, about 1 μm, or about 10 μm. In some aspects, the piezoelectric film is patterned and/or etched.

In some aspects, the method further comprises etching the piezoelectric film to provide conduits for one or more electrodes and/or to form a mesa, which designates the portion of the multilayer sheet in the outer turn (see FIG. 5).

In some aspects, the method includes disposing of the strain layer, wherein the strain layer includes two layers, and wherein, a first layer is in tension, and a second layer is in compression. In some aspects, the first layer is on a top side and the second layer is on a bottom side of the strained layer. In other aspects, the first layer is on the bottom side and the second layer is on the top side of the strained layer.

In yet other aspects, the strained layer includes a gradient of compression stress and/or tension stress. In some examples, the top side is primarily in tension and the bottom side is primarily in compression. In some aspects, the composition is a gradient from the topmost composition in tension and the bottom most composition in compression. In other aspects, the gradient of compression to tension is a result of varied deposition conditions. In yet other aspects, the strained layer is primarily in compression on the bottom side and the compressive stress gradually decreases toward the top side. In yet other aspects, the strained layer is in tension on the top side and the tensive stress gradually decreases toward the bottom side.

In some aspects, the method includes selectively etching the sacrificial layer is selectively from the planar multilayer sheet, which releases the strain layer film and subsequently curls up due to the expansion of the compressively strained layer and the contraction of the tensile stressed layer, thereby forming a strain-relieved layer. Resulting in the planar multilayer sheet transforming into a rolled-up tube. The process has directional control, dependent on the etch window orientation, and can be rolled into many turns. In some aspects, the number of turns can be 0.5, 1, 1.5, 2, 2.5, 3, etc.

In some aspects, the rolled-up tube is a self-rolled-up membrane (S-RuM) of MEMs from the multilayer sheet, which utilizes residual stress in the strain-relieved layer to roll up the planar multilayer sheet into 3D cylindrical multiturn architectures with <0.1 mm² areal footprint.

In some aspects, the areal footprint is about 10 mm², about 8 mm², about 6 mm², about 4 mm², about 2 mm², about 1 mm², about 0.8 mm², about 0.6 mm², about 0.4 mm², about 0.2 mm², about 0.1 mm² or less.

In some aspects, the method further includes disposing of a metal layer, wherein the metal layer includes an interrelated patterned to form an inductor and/or conductor and/or resistor in the rolled-up form.

In some aspects, the method further includes disposing of spacers atop the metal layer, which provides for a minimum distance between rolled-up layers. The spacer is one of a photoresist material or Au, Al, Cu, Ni, Ti, Cr, Pt, etc. The spacers prevent short circuiting in the curved article. An example multilayer sheet including spacer is shown in FIG. 6. A photoresist material includes one or more light-sensitive polymers and optionally a binding material. In preferred examples, photoresist materials produced by Merck, such as AZ 5209 E, AZ 5214 E, TI 35 E, T135ESX, AS 125nXT, AS 15nXT, AZ nLof 2020, AZ nLof 2035, AZ nLof 2070, AZ nLof 5510, AZ 1505, AZ 1512 HS, AZ 1514 H, AZ 1518, AZ MIR 701, AZ ECI 3007, AZ ECI 3012, AZ ECI 3027, AS TFP 650, among others can be used in the formation of the spacers.

In some aspects, the method further includes disposing of an insulating cover layer disposed atop the uppermost electrode layer, thereby separating a top electrode from the metal layer.

In some aspects, the method further includes applying a voltage across the first and second electrodes, thereby stretching or compressing an outer layer of the curved article.

An exemplary method includes forming an initial material stack consisting of a Ge sacrificial layer, SiNₓ stressed bilayer, Al bottom electrode, and AlScN layer on a sapphire substrate; etching AlScN to form a contact window for the bottom electrode and to define the top electrode; and depositing Al the etched regions. In the exemplary method, the thickness of the deposited Al closely matches the etch depth in order to prevent issues with rolling at this transition. The exemplary method further includes patterning a mesa in the AlSnN and conformally coating with an Al₂O₃ cover layer via ALD. The cover layer prevents shorting of the top electrode to the capacitor fingers and determines the rolling direction via an etch window (see FIG. 3B). Then, Au capacitor fingers and contacts are patterned above the cover layer, then an etch window in the cover layer is opened on one edge of the mesa. Finally, the sacrificial layer is released, forming a multi-turn article.

By integrating lithographically-patterned metal strips on top of the strained layers, S-RuM passive devices are formed, including inductors, transformers, interdigital capacitors, and resonators. In addition, monolithic S-RuM 2nd-order L-C filter networks have been formed by integrating both inductors and capacitors onto a single dielectric membrane. By manipulating the planar design of the metal contacts, the same device can function as a high-pass filter, low-pass filter, or resonator.

While static components have previously been fabricated, tunable components, especially tunable filter networks, are highly desired for advanced wireless communication devices. Described herein are S-RuM L-C filters with integrated piezoelectric materials, which allow for electrical manipulation and tuning. AlScN, with reported piezoelectric coefficients d₃₃ of 28 pm/V and −d₃₁ of 13 pm/V, exhibits a good balance between the high piezoelectric coefficients of lead zirconate titanate (PZT) and the thermal handling capability of AlN. Furthermore, its non-brittle nature allows AlScN to handle tensile stress, a key parameter in the S-RuM mechanism, much better than ceramic piezoelectric materials, such as PZT, making it particularly compatible with the S-RuM process.

By integrating thin film AlScN, sandwiched between two metal electrode layers, into 2-turn S-RuM L-C filters as an additional layer above the planar structure, the application of an electrical field across the piezoelectric film can cause a transverse displacement of up to a few micrometers. This will lead to a diameter modification of the outer turn of the rolled-up device. This field-dependent change of diameter can adjust the inductance and capacitance of S-RuM devices and enable fine-tuning of the frequency response of the lumped L-C network.

For S-RuM inductors, a significant mutual inductance between adjacent layers is introduced as the planar multilayer sheet is rolled up. A larger number of turns or a smaller diameter boosts this inductance. Tuning is even more evident in the rolled-up interdigital capacitors, which have an additional parallel plate capacitance due to the overlap of electrodes of opposite polarity on adjacent turns. If the overlap is maximized, the inter-turn capacitance dominates; if minimized, the inter-turn capacitance is negligible compared to the interdigital capacitance. Changing the diameter of the structure, and therefore the amount of overlap tunes the capacitance between the two extremes. When fully optimized, this can cause a change in capacitance of up to 20× for a simple two-turn S-RuM capacitor, which alone translates to a change of over 4× in the cutoff or resonant frequency of a second-order SRuM L-C filter. Such a two-turn tunable S-RuM L-C filter is designed to target the 1 MHz to 100 GHz resonant frequency range.

To further increase the possible tuning range, the two-turn structure can be repeated, such that every other turn has AlScN, without increasing the volume of the device significantly. This modifies the filter to target the MHz frequency range, such that tunability of more than 10× in the resonant frequency can be achieved as multiple L-C networks with different numbers of turns are fabricated, targeting an overall tuning range of 1 MHz to 10s of GHz.

This disclosure contemplates that the rolled-up capacitors may be utilized to achieve a significant increase in the capacitance while reducing its footprint compared to its planar counterpart, which is achieved by the capacitive coupling between each rolled-up turn. For example, a two-turn rolled-up capacitor has a 2D footprint seven-times smaller than when it was planar yet has a capacitance more than 17 times larger due to the overlapping capacitance introduced.

### EXAMPLES

Miniaturized passive electronic devices are critical components in RFICs. As the number of wireless technologies continues to grow, especially with the swift development of the Internet of Things, leading to crowding of the RF spectrum, the reconfigurability and tunability of RF components have become increasingly attractive. One approach to tunable RF passives, piezoelectric actuators, is particularly useful for MEMS applications due to their small size, fast response, and low power consumption.

The S-RuM platform is a MEMS approach that utilizes the residual stress in thin films to spontaneously roll up planar designs into 3D monolithic tubular structures. A stressed bilayer (tensile on compressive) is deposited on a sacrificial layer that, when etched, releases the stressed bilayer from the substrate, allowing it to relax and curl up into a multi-turn tube. By patterning a metal layer atop the stressed bilayer before rolling, various S-RuM passive devices have been demonstrated, including inductors [1]-[3], transformers [4], interdigital capacitors [5], [6], and LC networks [7]. S-RuM capacitors in particular are well-suited for tuning, as the capacitance, consisting of an interdigital capacitance between fingers on the same turn and an overlap capacitance between fingers on different turns, has been shown to have two extremes of a minimum and maximum determined by the degree of overlap of fingers of opposite polarity [5]. Given fixed finger dimensions, this overlap is dependent on the difference between the diameters of adjacent turns, making diameter tunability attractive.

The unique structure of S-RuM capacitors results in two sources of capacitance, an interdigital capacitance between adjacent fingers and a parallel-plate capacitance between fingers of opposite polarity on adjacent turns. For a given planar design, the amount of overlap of fingers of opposite polarity is determined by the rolled-up diameter. Typically, this diameter is determined before rolling by the amount of stress embedded within the SiNx stressed bilayer and the amount/thickness of subsequent materials deposited above. By integrating piezoelectric AlScN, post-rolling diameter tuning can be achieved, allowing overlap and thus capacitance tuning.

The planar design for tunable S-RuM capacitors is shown in FIG. 1A. The capacitor is designed to have approximately two turns after rolling, referred to as the “inner” and “outer” turns. A bottom electrode and AlScN layer span both turns; however, the top electrode is patterned such that only the outer turn is piezoelectrically-manipulatable. After rolling, the application of voltage to the top and bottom electrodes causes the outer turn to expand or contract, thus changing finger overlap, such as in FIG. 9. Interdigital finger dimensions are 5 μm×775 μm with 5 μm spacing. The capacitor electrodes are terminated by feedlines leading to contact pads. De-embedding open and thru structures were included for an open-thru de-embedding procedure detailed in previous work [1].

The fabrication process includes an initial material stack consisting of a Ge sacrificial layer, SiNₓ stressed bilayer, Al bottom electrode, and AlScN layer on a sapphire substrate. A contact window for the bottom electrode is opened by etching the AlScN. To define the top electrode, the AlScN is first partially etched, then Al deposited in the etched region. Care must be taken to ensure the thickness of the deposited Al closely matches the etch depth in order to prevent issues with rolling at this transition. The mesa is then defined and conformally coated with an Al₂O₃ cover layer via ALD. The cover layer prevents shorting of the top electrode to the capacitor fingers and determines the rolling direction via an etch window (see FIG. 3B). Au capacitor fingers and contacts are patterned above the cover layer, then an etch window in the cover layer opened on one edge of the mesa. Upon XeF₂ etching of the sacrificial layer, the structure rolls up into a multi-turn tube.

Al_{0.7}Sc_{0.3}N was deposited by Evatec AG with DC magnetron sputtering. Compressive stress (measured stress of −4 to −51 MPa) was minimized to reduce competition with the upper tensile layer of the SiNₓ stressed bilayer. AlScN etching was performed in an Oxford Plasmalab System 100 ICP-RIE. This process, based on [9], showed reduced redeposition of non-volatile etch byproducts, therefore minimizing unwanted material on the surface after etching, with an etch rate of approximately 51 nm/min.

Capacitance measurements were taken from 10 kHz to 10 MHz with a Keithley 4200A-SCS parameter analyzer equipped with a 4215-CVU. An attached 4201-SMU was used to apply voltage to the top and bottom electrodes for piezoelectric manipulation.

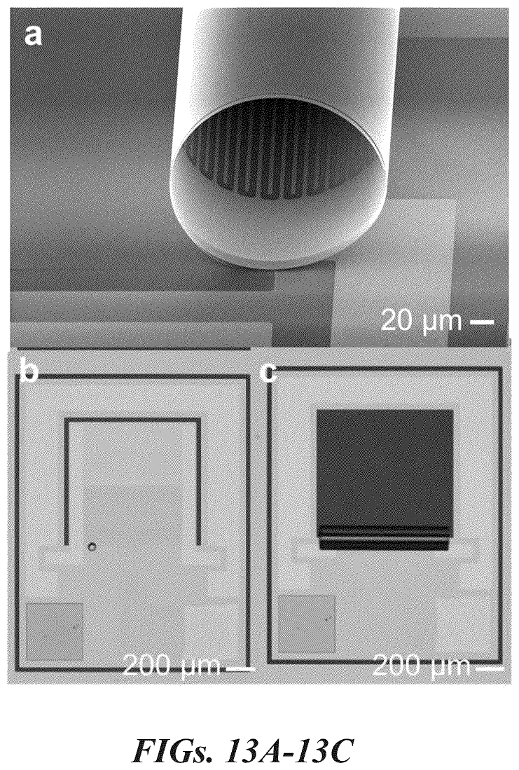

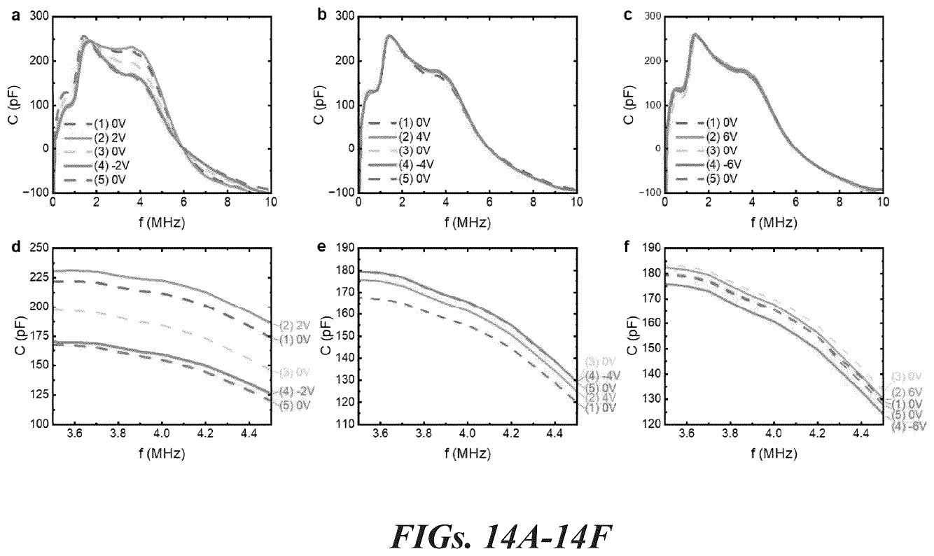

SEM and microscope images of a fabricated device are shown in FIGS. 13A-13C, with an inner diameter of 182 μm and a rolled-up tube footprint of approximately 0.18 mm². Plots of capacitance vs. frequency are shown in FIGS. 14A-14F. Three consecutive sets of measurements were taken with increasingly large, applied voltages of ±2 V (FIGS. 14A and 14D), ±4 V (FIGS. 14B and 14E), and ±6 V (FIGS. 14C and 14F). A measurement at 0 V was taken before and after each measurement with applied voltage, with the order of each measurement shown in parentheses before the voltage. As shown, capacitance changes with applied voltage, with a general increase in capacitance with positive voltages and vice versa for negative voltages. An exception is seen in FIGS. 14B and 14E, in which an opposite trend is observed. In comparison to a simple shift of the capacitor fingers on the outer turn, the piezoelectric expansion or contraction of the outer turn causes an increasingly large shift for each successive finger on the outer turn. For a large enough applied voltage, this could cause one set of overlapping fingers to have the same polarity while another set has opposite polarity. As such, total overlap of fingers of opposite polarity and thus capacitance will occasionally increase or decrease outside of the general trend.

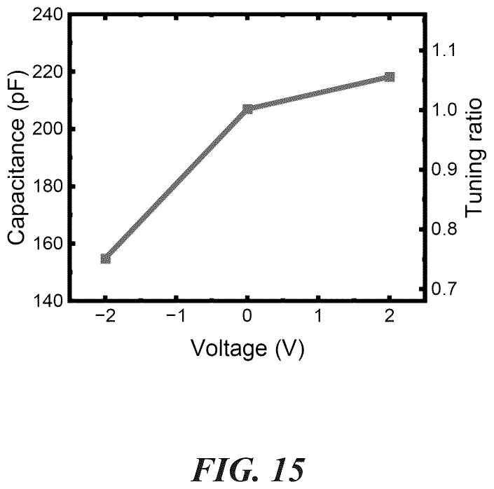

The largest changes in capacitance are seen near 4 MHz, zoomed in for FIGS. 14D-14F. A maximum change of 63 pF is observed between −2 and 2 V at 4.1 MHz, as seen in FIG. 14D, corresponding to a maximum tuning ratio of 1.41 and response of 15.75 pF/V between −2 and 2 V. The tuning ratio with respect to the capacitance at 0 V is shown in FIG. 15. As seen in all plots in FIGS. 14A-14F, capacitance does not fully recover to the same value for each measurement taken at 0 V, with a change from 207 to 179 to 150 pF at 4.1 MHz seen for the 1st, 2nd, and 3rd 0 V measurements, respectively, in FIG. 14D. Due to the multi-turn structure of the capacitors, the turns may come into contact at different regions around the tube, changing as the outer turn shifts during piezoelectric manipulation. The friction due to this contact inhibits the expansion or contraction of the outer turn, preventing the capacitor from fully recovering to its original position. Additional measurements further distort the capacitor from its original shape, resulting in the decrease in tuning ratio seen for the larger applied voltages, with the difference in capacitance from −4 to 4 V and −6 to 6 V decreasing to 4 and 7 pF, respectively. This hysteresis, largely resulting from friction between rolled layers, was corrected by the addition of “spacer” structures to uniformly space the turns apart along the circumference of the tube, allowing the outer turn to freely deform in the regions between the spacer structures. The maximum measured capacitance is 262 pF at 1.4 GHz with an applied voltage of 6 V, corresponding to a capacitance density of 1.6 nF/mm². The total capacitance and tuning ratio of the devices can be easily modified to target different capacitance and frequency ranges by adjusting the dimensions and number of the interdigital electrode fingers. Taking advantage of the 2D to 3D nature of the S-RuM platform, this can be done with a simple modification of the patterned metal device layer, with little to no effect on fabrication complexity or the final rolled-up device footprint.

In this work, 3D miniaturized piezoelectrically-actuated tunable capacitors are fabricated and characterized, demonstrating a piezoelectric-driven tuning scheme enabled by the strain-induced S-RuM platform. Taking advantage of the diameter-dependent capacitances of previously demonstrated S-RuM capacitors, experimental data of the prototype capacitors shows large tuning responses achieved at low applied voltages. In addition, the capacitors are easily reconfigurable using 2D conventional planar processing techniques to target various capacitance and frequency ranges. By combining with S-RuM inductors, the improved capacitors can be used to create ultra-small LC filters operating in the MHz to GHz frequency range for integration into RFICs.

### DISCUSSION

A variety of tunable MEMS filters for high-frequency applications have been developed, varying in their actuation method, tuned parameter and range, and footprint. In comparison to other methods, piezoelectrically-actuated tunable MEMS filters typically have small sizes, fast responses, and low power consumption. Current state-of-the-art piezoelectrically-tunable filters make use of 2D microstrip resonators or require complex processing in order to form 3D disc flexure resonators. In comparison, L-R-C filter networks are described herein as an alternative to resonators. In addition, the method of making the self-rolled-up membrane for L-R-C filters requires a relatively simple monolithic fabrication process in order to transform 2D structures into 3D cylindrical multiturn architectures, dramatically minimizing footprint. S-RuM L-C filters have been patented (U.S. Pat. No. 10,003,317, which is expressly incorporated herein). Piezoelectrically-manipulated S-RuM structures have not been demonstrated previously.

Integrating thin piezoelectric material such as (and not limited to) AlScN onto the S-RuM platform allows 3D cylindrical multiturn architectures to be tuned by varying the radius of curvature of the S-RuM platform. AlScN, with reported piezoelectric coefficients d₃₃ of 28 pm/V and d₃₁ of 13 pm/V, is a piezoelectric material that exhibits a good balance between the high piezoelectric coefficients of PZT and the thermal handling capability of AlN. Furthermore, its non-brittle nature allows AlScN to handle tensile stress, a key parameter in the S-RuM mechanism, much better than the common ceramic piezoelectric materials, such as PZT, making it particularly compatible with the S-RuM process.

Key aspects include the integration of piezoelectric material into a curved surface that is realized by the self-rolled-up membrane platform. Deliberate placement of contact electrodes for piezoelectric material enables local mechanical tuning (stretching/shrinking) of piezoelectric material to tune the attached passive components. Due to the nature of self-rolled-up membranes, this can especially affect the alignment of electrode fingers in the MEMS interdigital capacitor, resulting in the manipulation of passive devices, such as various filter networks, that need the integration of capacitive components.

The miniaturization of passive electronic components to enable more efficient use of chip area and integration into a wider set of applications is of great importance to many fields including power electronics and RFICs. The piezoelectrically-actuated tunable filters can achieve tuning in the MHz to GHz frequency range while combining multiple inductor and capacitor components into a monolithic fabrication process that dramatically minimizes the component footprint, which was not previously shown in the field.

It is contemplated that any piezoelectric material, exhibiting a high piezoelectric coefficient when it becomes a thin membrane, is a suitable material for the exemplary articles. It is contemplated that the forming the piezoelectric material by epitaxially grown by MBE or physically sputtered by magnetron sputterer, provides acceptable results. Fabrication complexity to integrate and then apply enough voltage to allow manipulation of the material is another key obstacle. In order to have significance to the invention, simplistic fabrication and CMOS compatibility must be retained. Continuing advancement and optimization of fabrication steps and tools can solve these issues. The current working frequency limit to self-rolled-up membrane devices is in the tens of giga-Hertz. It is contemplated that optimization and change of design to improve the working frequency of future RF technology may result in achievable frequency ranges beyond 100 GHz.

Fabrication of the S-RuM platform is simple, allowing for a configurable monolithic integration of rolled-up inductive and capacitive components without adding any additional complexity to the fabrication process. High-pass filters, low-pass filters, and resonators can be fabricated depending on the configuration of the induction and capacitive components, as well as signal contacts. It is contemplated that the piezoelectric tuning of rolled-up capacitors can allow for integration into existing L-C networks and advance the technology into a multistage tunable filter or resonator networks. Further, the S-RuM platform can be able to push for further miniaturization and lower power consumption at higher frequencies for these tunable filters.

Some of the methods of making of rolled-up structures can be found in U.S. Pat. Nos. 10,003,317; 9,224,532; 9,018,050; 10,276,942; 10,490,328; 11,031,456; and U.S. Publication Nos. 20150099116A1, 20210103824A1, the contents of which are hereby incorporated by reference in their entirety herein.

### Exemplary Aspects

Exemplary aspect 1. An article comprising: a multilayer sheet configured to be present in a compressive and/or tensile stress, wherein the multilayer sheet is rolled-up to form a curved article, and wherein the multilayer sheet comprises a piezoelectric film configured to tune a radius of curvature of the article upon application of an electrical field across the piezoelectric film.

Exemplary aspect 2. The article of exemplary aspect 1, wherein the rolled-up curved article comprises one or more turns of the multilayer sheet along a longitudinal axis.

Exemplary aspect 3. The article of exemplary aspect 1 or 2, wherein a number of turns comprise integral and fractional numbers.

Exemplary aspect 4. The article of any one of exemplary aspects 1-3, wherein the article has a tubular, spiral, or helical form.

Exemplary aspect 5. The article of exemplary aspect 4, wherein the article has a 3D cylindrical multiturn architecture.

Exemplary aspect 6. The article of any one of exemplary aspects 1-5, wherein the multilayer sheet further comprises a first electrode and a second electrode, wherein the piezoelectric film is disposed between the first and the second electrodes.

Exemplary aspect 7. The article of any one of exemplary aspects 1-6, wherein the curved article has an on-wafer footprint of about 10 mm² or less.

Exemplary aspect 8. The article of any one of exemplary aspects 1-7, wherein the piezoelectric film is patterned.

Exemplary aspect 9. The article of any one of exemplary aspects 1-8, wherein the piezoelectric film has a thickness of about 1 nm-10 μm.

Exemplary aspect 10. The article of any one of exemplary aspects 1-9, wherein the piezoelectric film is comprised of a piezoelectric material having a range of piezoelectric coefficient d33 of about 5 to 150 pm/V and d31 of about −5 to −50 pm/V and is pliable.

Exemplary aspect 11. The article of any one of exemplary aspects 1-10, wherein the multilayer sheet further comprises a strain-relieved layer.

Exemplary aspect 12. The article of exemplary aspect 11, wherein the strain-relieved layer comprises two layers, and wherein, in an unrolled configuration of the multilayer sheet, a first layer of the two layers is in tension, and a second layer of the two layers is in compression.

Exemplary aspect 13. The article of any one of exemplary aspects 1-12, wherein the multilayer sheet further comprises a metal-containing layer.

Exemplary aspect 14. The article of any one of exemplary aspects 1-13, wherein the article is a radio frequency component.

Exemplary aspect 15. The article of any one of exemplary aspects 1-14, wherein the article is a tunable L-circuit component, R-circuit component, C-circuit component, L-R-C-filter network, L-C filter network, antenna, transformer, switch, valve, or any combination thereof.

Exemplary aspect 16. The article of exemplary aspect 15, wherein when the article is the tunable R-circuit component, C-circuit component, L-R-C filter network, L-C filter network, or any combination thereof, the article is tunable in a 1 MHz to 100 GHz frequency range.

Exemplary aspect 17. The article of exemplary aspect 15 or 16, wherein when the article is the tunable R-circuit component, C-circuit component, L-R-C filter network, L-C filter network, or any combination thereof, the article is tunable in a 15-25 GHz frequency range.

Exemplary aspect 18. A device comprising one or more of the curved articles of any one of exemplary aspects 1-17.

Exemplary aspect 19. A tunable article, wherein the tunable article is an L, R, and/or C circuit component or any combination thereof, the tunable article comprising: a multilayer sheet in a rolled configuration comprising: a strain-relieved layer; a first electrode layer; a piezoelectric layer; a second electrode layer; and a metal-containing layer, wherein the piezoelectric layer is patterned along a longitudinal axis; wherein the first and second electrodes are exposed on an outside of the tunable article for electrical contact with a voltage supply, and wherein a diameter of the multilayer sheet is tuned by applying an electric voltage across the tunable article.

Exemplary aspect 20. The tunable article of exemplary aspect 19, wherein the piezoelectric layer comprises a piezoelectric material having a range of piezoelectric coefficient d33 of about 5 to 150 pm/V and d31 of about −5 to −50 pm/V and is pliable.

Exemplary aspect 21. The tunable article of exemplary aspect 19 or 20, wherein the piezoelectric layer comprises one or more of ZnO, AlN, BNT, PVDF, LiNbO3, or AlXN, where X is chosen from Sc, B, Er, Cr, Ti, V, Y, Yb, Ta, In, Mg, Zr, Nb, Li, or combinations thereof.

Exemplary aspect 22. The tunable article of any one of exemplary aspects 19-21, wherein the tunable article is tunable in a 1 MHz to 100 GHz frequency range.

Exemplary aspect 23. The tunable article of any one of exemplary aspects 19-22, wherein the tunable article is tunable in a 15-25 GHz frequency range.

Exemplary aspect 24. The tunable article of any one of exemplary aspects 19-23, wherein the rolled configuration of the multilayer sheet comprises one or more turns about a longitudinal axis.

Exemplary aspect 25. The tunable article of any one of exemplary aspects 19-24, wherein the rolled configuration of the multilayer sheet has an on-wafer footprint of about 10 mm² or less.

Exemplary aspect 26. The tunable article of any one of exemplary aspects 19-25, wherein the strain-relieved layer comprises two layers, and wherein, in an unrolled configuration of the multilayer sheet, a first layer of the two layers is in tension, and a second layer of the two layers is in compression.

Exemplary aspect 27. The tunable article of any one of exemplary aspects 19-26, wherein the metal-containing layer comprises an interrelated pattern, that when in the rolled configuration, forms a rolled-up inductor, capacitor, resistor, or combinations thereof on the strain-relieved layer.

Exemplary aspect 31. The tunable article of any one of exemplary aspects 19-30, wherein the tunable article is an L-R-C filter network.

Exemplary aspect 32. The tunable article of any one of exemplary aspects 19-30, wherein the tunable article is an L-C filter network.

Exemplary aspect 33. A device comprising: one or more of tunable articles of any one of exemplary aspects 19-32.

Exemplary aspect 34. A method of making a curved article, the method comprising: forming a sacrificial layer on a substrate; forming a strained layer on the sacrificial layer, the strained layer comprising an upper portion under tensile stress and a lower portion under compressive stress, the strained layer being held on the substrate by the sacrificial layer; forming a patterned piezoelectric layer on the strained layer, the patterned piezoelectric layer comprising a first electrode, a thin film of piezoelectric material, and a second electrode; initiating removal of the sacrificial layer from the substrate, thereby releasing an end of the strained layer; and continuing removal of the sacrificial layer, thereby allowing the strained layer to move away from the substrate and roll up to a rolled configuration to relieve strain in the strained layer, thereby forming a curved article.

Exemplary aspect 35. The method of exemplary aspect 34 comprising: applying a voltage across the first and second electrodes, thereby stretching or compressing an outer layer of the curved article.

Exemplary aspect 37. The method of any one of exemplary aspects 34-35, wherein the piezoelectric layer is formed by epitaxial growth, atomic layer deposition, or sputtering of the piezoelectric material.

Exemplary aspect 38. The method of any one of exemplary aspects 35-37, wherein the piezoelectric material exhibits a range of piezoelectric coefficient d33 of about 5 to 150 pm/V and d31 of about −5 to −50 pm/V and is pliable (e.g., non-brittle).

Exemplary aspect 39. The method of any one of exemplary aspects 35-38, wherein the thin film of piezoelectric material has a thickness of about 1 nm-about 10 μm.

### REFERENCES

1. Deterministic assembly of complex, three-dimensional architectures by compressive buckling (U.S. Ser. No. 10/538,028B2).
2. Capacitor and process for producing thereof (US20170162333A1).
3. Waveguide resonator component and method for the production thereof (WO2014140206A1).
4. Monolithic Heterogeneous Integration of 3D Radio Frequency L-C Elements by Self-Rolled-Up Membrane Nanotechnology (Advanced Functional Materials, 2020, DOI: 10.1002/adfm.202004034).
5. Self-Rolled-Up Aluminum Nitride-Based 3D Architectures Enabled by Record-High Differential Stress (Applied Materials and Interfaces, 2022, DOI:10.1021/acsami.2c06637).
6. Monolithic mtesla-level magnetic induction by self-rolled-up membrane technology (Science Advances, 2020, DOI: 10.1126/sciadv.aay4508).
7. On-Chip Inductors with Self-Rolled-Up SiNx Nanomembrane Tubes: A Novel Design Platform for Extreme Miniaturization (Nano Letters, 2012, DOI:10.1021/n1303395d).
8. Ultra-Small, High-Frequency, and Substrate-Immune Microtube Inductors Transformed from 2D to 3D (Scientific Reports, 2015, DOI: 10.1038/srep09661).
9. Monolithic radio frequency SiNx self-rolled-up nanomembrane interdigital capacitor modeling and fabrication (Nanotechnology, 2019, DOI: 10.1088/1361-6528/ab244b).
10. Physical Modeling of Monolithic Self-Rolled-Up Microtube Interdigital Capacitors (IEEE Transactions on Components, Packaging and Manufacturing Technology, 2022, DOI:10.1109/TCPMT.2021.3128884).
11. Graphene sensor: aip.scitation.org/doi/full/10.1063/5.0046628
12. Tunable optical filter based on self-rolled-up microtube incorporating nematic liquid crystal (Optical Materials, 2017, DOI: 10.1016/j.optmat.2017.03.054).
13. Temperature controlled actuator? iopscience.iop.org/article/10.1088/0964-1726/20/8/085016/pdf
14. Light controlled actuator onlinelibrary.wiley.com/doi/epdf/10.1002/adma.201904224

### EXAMPLE REFERENCES

[1] W. Huang et al., “Monolithic mtesla-level magnetic induction by self-rolled-up membrane technology,” Sci. Adv., vol. 6, no. 3, p. eaay4508, January 2020, doi: 10.1126/sciadv.aay4508.
[2] W. Huang, X. Yu, P. Froeter, R. Xu, P. Ferreira, and X. Li, “On-Chip Inductors with Self-Rolled-Up SiNx Nanomembrane Tubes: A Novel Design Platform for Extreme Miniaturization,” Nano Lett., vol. 12, no. 12, pp. 6283-6288, December 2012, doi: 10.1021/n1303395d.
[3] X. Yu et al., “Ultra-Small, High-Frequency and Substrate-Immune Microtube Inductors Transformed from 2D to 3D,” Sci. Rep., vol. 5, no. 1, p. 9661, April 2015, doi: 10.1038/srep09661.
[4] W. Huang et al., “Three-dimensional radio-frequency transformers based on a self-rolled-up membrane platform,” Nat. Electron., vol. 1, no. 5, pp. 305-313, May 2018, doi: 10.1038/s41928-018-0073-5.
[5] L. Sang et al., “Monolithic radio frequency SiNx self-rolled-up nanomembrane interdigital capacitor modeling and fabrication,” Nanotechnology, vol. 30, no. 36, p. 364001, September 2019, doi: 10.1088/1361-6528/ab244b.
[6] X. Luo et al., “Physical Modeling of Monolithic Self-Rolled-Up Microtube Interdigital Capacitors,” IEEE Trans. Compon. Packag. Manuf. Technol., vol. 12, no. 2, pp. 359-367, February 2022, doi: 10.1109/TCPMT.2021.3128884.
[7] Z. Yang et al., “Monolithic Heterogeneous Integration of 3D Radio Frequency L-C Elements by Self-Rolled-Up Membrane Nanotechnology,” Adv. Funct. Mater., vol. 30, no. 40, p. 2004034, October 2020, doi: 10.1002/adfm.202004034.
[8] K. Umeda, H. Kawai, A. Honda, M. Akiyama, T. Kato, and T. Fukura, “Piezoelectric properties of ScAIN thin films for piezo-MEMS devices,” in 2013 IEEE 26th International Conference on Micro Electro Mechanical Systems (MEMS), Taipei, Taiwan: IEEE, January 2013, pp. 733-736. doi: 10.1109/MEMSYS.2013.6474347.
[9] Z. Luo, S. Shao, and T. Wu, “Al0.78Sc0.22N Lamb Wave Contour Mode Resonators,” IEEE Trans. Ultrason. Ferroelectr. Freq. Control, vol. 69, no. 11, pp. 3108-3116, November 2022, doi: 10.1109/TUFFC.2021.3136337.
[10] J. Startt, et. al., “Unlocking AlN Piezoelectric Performance with Earth-Abundant Dopants,” Adv. Electron. Mater. 2023, 9, 2201187, doi.org/10.1002/aelm.202201187.

What is claimed is:

1. An article comprising:
a multilayer sheet configured to be present in a compressive and/or tensile stress, the multilayer sheet comprising:
a piezoelectric film;
a first electrode and a second electrode, wherein the piezoelectric film is disposed between the first and the second electrodes;
wherein the multilayer sheet is rolled-up to form a curved article, and
wherein the piezoelectric film tunes a radius of curvature of the article upon application of an electric voltage across the piezoelectric film.

2. The article of claim 1, wherein the rolled-up curved article comprises one or more turns of the multilayer sheet along a longitudinal axis and has an on-wafer footprint of about 10 mm² or less.

3. The article of claim 1, wherein the piezoelectric film has a thickness of about 1 nm to about 10 μm.

4. The article of claim 1, wherein the piezoelectric film is comprised of a piezoelectric material having a range of piezoelectric coefficient d₃₃ of about 5 to 150 pm/V and d₃₁ of about −5 to −50 pm/V and is pliable (e.g., non-brittle).

5. The article of claim 1, wherein the multilayer sheet further comprises a strain-relieved layer, wherein the strain-relieved layer comprises two layers, and wherein, in an unrolled configuration of the multilayer sheet, a first layer of the two layers is in tension, and a second layer of the two layers is in compression.

6. The article of claim 1, further comprising a third electrode, wherein the first electrode is laterally aligned with the second electrode, wherein the piezoelectric film is disposed between the third electrode on a bottom side and the first and second electrodes on a top side, and wherein the top side of the piezoelectric film is etched such that a portion of the piezoelectric film is between the first and second electrode.

7. The article of claim 1, the article further comprising a second piezoelectric film and a third electrode, wherein the second piezoelectric film is disposed between the second electrode and the third electrode.

8. The article of claim 7, further comprising a second piezoelectric film, a fourth electrode and a fifth electrode, wherein the fourth electrode and the fifth electrode are laterally aligned and separated by an etched portion of the second piezoelectric film, and wherein the second piezoelectric film being disposed between the third electrode and the fourth and fifth electrodes.

9. A tunable article, wherein the tunable article is an L, R, and/or C circuit component or any combination thereof, the tunable article comprising:
a multilayer sheet in a rolled configuration comprising:
a strain-relieved layer;
a first electrode layer;
a piezoelectric layer;
a second electrode layer; and
a metal-containing layer,
wherein the metal-containing layer is patterned;
wherein the first and second electrodes are exposed on an outside of the tunable article for electrical contact with a voltage supply, and
wherein a diameter of the multilayer sheet is tuned by applying an electric voltage across the tunable article.

10. The tunable article of claim 9, wherein the piezoelectric layer comprises a piezoelectric material having a range of piezoelectric coefficient d₃₃ of about 5 to 150 pm/V and d₃₁ of about −5 to −50 pm/V and is pliable.

11. The tunable article of claim 9, wherein the piezoelectric layer comprises one or more of ZnO, AlN, BNT, PVDF, LiNbO3, or AlXN, where X is chosen from Sc, B, Er, Cr, Ti, V, Y, Yb, Ta, In, Mg, Zr, Nb, Li, or combinations thereof.

12. The tunable article of claim 9, wherein the tunable article is tunable in an about 1 MHz to about 100 GHz frequency range.

13. The tunable article of claim 9, wherein the rolled configuration of the multilayer sheet comprises one or more turns about a longitudinal axis, and wherein the rolled configuration of the multilayer sheet has an on-wafer footprint of about 10 mm² or less.

14. The tunable article of claim 9, wherein the strain-relieved layer comprises two layers, and wherein, in an unrolled configuration of the multilayer sheet, a first layer of the two layers is in tension, and a second layer of the two layers is in compression.

15. The tunable article of claim 9, wherein the metal-containing layer comprises an interrelated pattern, that when in the rolled configuration, forms a rolled-up inductor, capacitor, resistor, or combinations thereof on the strain-relieved layer.

16. The tunable article of claim 15, wherein the diameter of the rolled multilayer sheet is compressed or expanded, causing the rolled up interrelated pattern to partially or fully overlap.

17. The tunable article of claim 9, further comprising a spacer, wherein the spacer comprises a photoresist material, Au, Al, Cu, Ni, Ti, Cr, Pt, or combinations thereof.

18. The tunable article of claim 9, wherein the tunable article is an L-R-C filter network, L-C filter network, L-circuit component, R-circuit component, C-circuit component, L-R-C-filter network, antenna, transformer, switch, valve, or any combination thereof.

19. A method of making a curved article, the method comprising:
forming a sacrificial layer on a substrate;
forming a strain layer on the sacrificial layer, the strain layer comprising a first portion under tensile stress and a second portion under compressive stress, the strain layer being held on the substrate by the sacrificial layer;
forming a piezoelectric layer on the strain layer, the piezoelectric layer comprising a first electrode, a film of piezoelectric material, and a second electrode; and
removing the sacrificial layer from the substrate, thereby releasing an end of the strain layer, forming a strain-relieved layer,
wherein the strain-relieved layer moves away from the substrate, forming a curved article.

20. The method of claim 19 comprising applying a voltage across the first and second electrodes, thereby stretching or compressing an outer layer of the curved article.

21. The method of claim 19, wherein the piezoelectric film is formed by epitaxial growth, atomic layer deposition, or sputtering of the piezoelectric material, and wherein a piezoelectric film thickness is about 1 nm to about 10 μm.
